(19) United States
(12) Patent Application Publication
(10) Pub. No.: US 2004/0171252 A1
(43) Pub. Date: Sep. 2, 2004

(54) REDUCED CONTAMINATION OF TOOLS IN SEMICONDUCTOR PROCESSING

(76) Inventors: Haoren Zhuang, Tokyo (JP); Katsuaki Natori, Tokyo (JP); Gerhard Beitel, Kanagawa (JP); Bum-ki Moon, Tokyo (JP); Moto Yabuki, Tokyo (JP); Yoshitaka Tsunashima, Tokyo (JP); Karl Hornik, Kanagawa (JP)

Correspondence Address: HORIZON IP PTE LTD, 166 Kallang Way, 6th Floor, SINGAPORE 349249, SG

(21) Appl. No.: 10/248,898

(22) Filed: Feb. 28, 2003

(51) Int. Cl. H01L 21/302; H01L 21/461

(52) U.S. Cl. 438/689

(57) ABSTRACT

An improved method of reducing contamination in processing of ICs is disclosed. The method includes forming a contamination protection layer on at least the back surface of the substrate. The contamination protection layer comprises a low diffusion factor and can be cleaned efficiently. In one embodiment, the contamination protection layer comprises HCD silicon nitride.

### BACKGROUND OF INVENTION

The fabrication of integrated circuits (ICs) involves the formation of features on a substrate that make up circuit components, such as transistors, resistors and capacitors, and the interconnection of such components. To form the features, layers are repeatedly deposited on the substrate and patterned as desired. Lithographic techniques are used to pattern the device layer or layers. Such techniques use an exposure source to project a light image from a mask onto a photoresist (resist) layer formed on the surface of the substrate. The light illuminates the resist layer, exposing it with the desired pattern. Depending on whether a positive or negative tone resist is used, the exposed or unexposed portions of the resist layer are removed. The portions not protected by the resist are then, for example, etched to form the features in the substrate.

Referring to FIG. 1, a semiconductor substrate 101 is shown. The substrate includes one or more device layers 140 which are deposited on the substrate. The device layers, for example, are used to form features that serve as components of an IC. During processing, the substrate is moved from tool to tool for different stages of processing. Elements 163, such as chemicals, from a stage of processing can be deposited on the backside 105 and sides 103 of the substrate. The elements can be incompatible or harmful to the subsequent stages of processing. Also, these elements can be transferred to the other tools, contaminating the other tools. Additionally, the elements can diffuse through the substrate, contaminating it.

To prevent cross-contamination of processes and tools as well as contamination of the substrate, a CAP layer 275 comprising silicon nitride is deposited on the bottom and sides of the substrate by low pressure chemical vapor deposition (LP-CVD), as shown in FIG. 2. The harmful elements are deposited on the surface of the silicon nitride layer. Due to the low diffusion factor of silicon nitride, the elements remain essentially of the surface. A clean step is performed after process is completed, etching the silicon nitride layer to remove a certain thickness from its surface. Removing a portion of the surface of the silicon nitride layer thus removes the elements thereon. Conventionally, hydrofluoride (HF) chemistry is used to etch the silicon nitride layer surface.

However, LP nitrides have a slow etch rate, reducing cleaning efficiency. Additionally, due the low etch rate, an etch solution with a very high concentration of HF is needed (e.g., about 20%). The use of an etch solution with high concentration of HF can be harmful to the tools, the environment, as well as increasing health risk to workers. To avoid using etch solutions with high concentrations of HF, tetraethylorthosilicate (TEOS) has been proposed instead of LP nitride. Although TEOS has a higher etch rate, it has a higher diffusion factor, enabling the elements to diffuse deeper into the layer. This results in a longer clean time to etch enough of the TEOS layer to ensure that the elements are removed, thus decreasing clean efficiency. Also, a much thicker TEOS layer is therefore needed in order to provide the same protection as the LP nitride. This increases the risk of delamination or pealing from the substrate.

From the foregoing discussion, it is desirable to provide an improved layer for protecting the substrate from contaminants.

### SUMMARY OF INVENTION

The invention relates generally to manufacturing of ICs. More particularly, the invention relates to reducing contamination in manufacturing of ICs. In one embodiment, a contamination protection layer is formed on at least a back surface of the substrate. Preferably, the contamination protection layer is formed on at least the back and side surfaces. The contamination protection layer comprises a low diffusion factor and can be cleaned efficiently. In one embodiment, the diffusion factor of the contamination protection layer is less than that of TEOS. In one embodiment, the contamination protection layer comprises HCD silicon nitride.

The contamination protection layer is formed on the substrate prior to a critical process. After a critical process, it is cleaned to remove the harmful elements from the contamination protection layer. In one embodiment, the contamination protection layer is cleaned using a clean solution comprising HF diluted in ozone water. In one embodiment, the clean solution comprises about 0.2 3% DHF with >10 ppm OZW. Preferably, the clean solution comprises about 0.5-2% DHF with >15 ppm OZW.

### BRIEF DESCRIPTION OF DRAWINGS

FIG. 1 shows a semiconductor substrate during a process;

FIG. 2 shows a semiconductor substrate with conventional CAP layer; and

FIGS. 3-4 show a process in accordance with one embodiment of the invention.

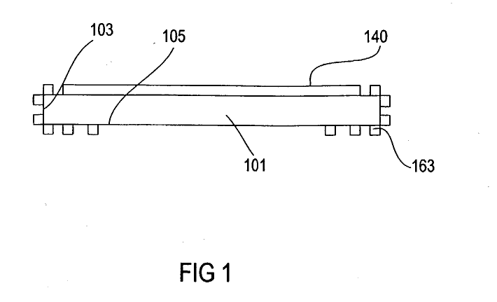

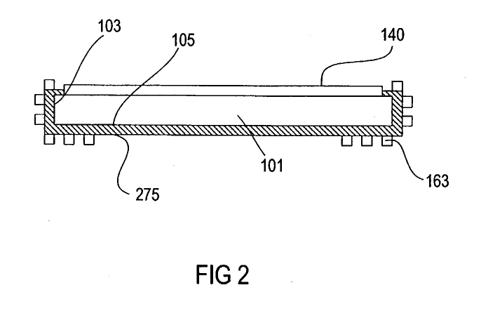

### DETAILED DESCRIPTION

The invention relates generally to the fabrication of ICs. The ICs, for example, are memory ICs with an array of memory cells. In one embodiment, the memory cells are ferroelectric memory cells. Forming other types of ICs are also useful. Such ICs may or may not be embedded with an array of memory cells. Generally, a plurality of ICs are formed on a semiconductor substrate, such as a silicon wafer, in parallel. After processing is finished, the wafer is diced to separate the ICs into individual chips. The chips are then packaged, resulting in a final product that is used in, for example, consumer products such as computer systems, cellular phones, personal digital assistants (PDAs), and other electronic products. In particular, the invention relates to reducing cross-contamination of tools, processes, as well as contamination of the wafer on which the ICs are formed.

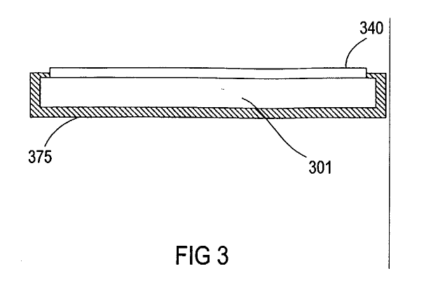

FIG. 3 shows an embodiment in accordance with one embodiment of the invention. As shown, a semiconductor substrate 301 is provided. The substrate, for example, is semiconductor wafer comprising of silicon. Other types of substrates can also be useful. Depending on the stage of processing, the substrate can include one or more device layers 340. The substrate may also include features located beneath the device layers. Alternatively, the substrate may be a bare substrate prior to the first stage of processing.

The device layers are used to create features to form components of the IC. In one embodiment, the device layers are used to form capacitors. The layers of a capacitor include, for example, a dielectric layer between first and second conductive layers. Preferably, the layers are used to form ferroelectric capacitors. Such layers include a ferroelectric layer between first and second electrodes. The ferroelectric layer can be PZT while the electrode layers can be a noble metal such as platinum. Other ferroelectric and conductive materials, such as SBT, SRO and Ir can also be used.

The backside of the substrate is coated is coated with a contamination protection layer 375. Preferably, the edges of the substrate are also coated with the contamination protection layer. In one embodiment, the substrate is coated with a contamination protection layer prior to a process where contamination of the substrate or cross-contamination of tools is an issue or concern. Such a process, for example, is referred to as a critical process. In a complete process flow, there may be more than one critical process. Preferably, the contamination protection layer is formed prior to the first critical process and should be sufficiently thick to accommodate all subsequent critical processes of the process flow. Alternatively, the contamination protection layer can be removed after each critical process and reapplied prior to the next critical process or a combination of providing a protection layer which protects some of the critical processes and reapplied for others.

The contamination protection layer comprises a material having a low diffusion factor and can be cleaned efficiently to avoid the use of clean solutions with high concentrations of HF. In one embodiment, the contamination layer comprises a diffusion factor lower than that of TEOS. The etch rate of the contamination protection layer is higher than that of silicon nitride (e.g., greater than about 2.5A/min in a 1/200 diluted HF solution) used in conventional CAP layers. Preferably, the etch rate of the contamination protection layer is at least equal to about 4A/min in a 1/200 diluted HF solution. More preferably, the etch rate of the contamination protection layer is at least equal to about 5A/min in a 1/200 diluted HF solution.

In one embodiment, the contamination protection layer comprises a low epsilon (k) silicon nitride. In one embodiment, the contamination layer comprises low k silicon nitride, where k is less than about 7.5, preferably k is less than 7.3, more preferably, k from about 5 to 7.3. The low k silicon nitride preferably comprises hexachlorodisilane (HCD) silicon nitride. Other types of low k silicon nitride are also useful. In another embodiment, the contamination protection layer comprises porous silicon nitride having a density less than about 2.8. Preferably, the density of the porous silicon nitride is less than about 2.6.

The HCD silicon nitride is deposited by, for example, CVD, such as LP CVD. For HCD silicon nitride, hexachlorodisilane is used. Other deposition techniques can also be useful. Typically, the deposition process is a batch process which deposits the contamination protection layer on all surfaces of the substrate. If necessary, the contamination protection layer covering at least the chip region (e.g., region of the substrate where ICs or components are formed) on the top surface of the substrate is removed. This leaves the edges on the top, sides, and bottom of the substrate protected by the contamination protection layer. This is achieved, for example, by masking the non-chip region on the top surface of the substrate and etching the protection layer in the chip region. The etch, for example, comprises a wet etch. Other types etch techniques, such as reactive ion etch (RIE) are also useful. Preferably, the protection layer is etched selective to the material below, such as the substrate or silicon oxide. Alternatively, a timed etch can be performed to remove the protection layer.

The thickness of the protection layer is sufficient to prevent the by-products from contaminating the substrate. Preferably, the thickness of the protection layer is sufficient to protect the substrate during other critical processes of the process flow. More preferably, the thickness of the protection layer is sufficient to protect the substrate during all other critical processes of the process flow. In one embodiment, the thickness of the contamination protection layer is about 100 nm. Other thicknesses are also useful, depending on the application and material.

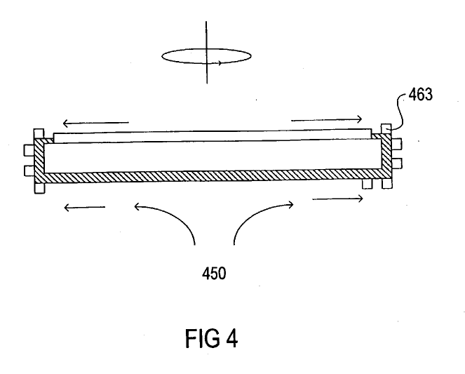

Referring to FIG. 4, the substrate is processed in a chamber 450 of a process tool. In one embodiment, the tool performs a critical process. The critical process, for example, is an etch process such as reactive ion etch (RIE) to pattern the layers. In one embodiment, the layers are patterned to form capacitors of memory cells. Preferably, the process patterns the layers to form ferroelectric capacitors. Forming other types of features or other types of critical processes, such as RTA, are also useful. The layers are patterned in an etch tool, such as an RIE tool.

During the process, byproducts are produced. Some of the byproducts 463 are, for example, deposited on the sides and bottom of the substrate. These byproducts can be harmful to subsequent processes. In the case where ferroelectric capacitors are formed, harmful byproducts can include, for example, platinum, zirconium, strontium, iridium, and/or lead. Due to the low diffusion factor of the contamination protection layer, diffusion of the harmful byproducts through the layer is inhibited. The harmful byproducts diffuse, for example, into the contamination protection layerabout 1-3 nm.

After the process is completed, the substrate is taken out of the process tool and cleaned to remove the contaminants. In one embodiment, the contaminants are removed by removing at least a portion of the contamination protection layer. In one embodiment, a sufficient amount of protection layer is removed so that the levels of the harmful byproducts are below a specified level. The specified level, for example, is equal to about 1 E10 atm/cm². Other levels can also be useful, depending on the application. Typically, about 5 nm of protection layer is removed.

In one embodiment, the contamination protection layer is removed by a wet etch. The wet etch can be performed in, for example, a spin-type etch tool. Other types of tools can also be used. The wet etch comprises a hydrofluoric (HF) solution. The HF solution includes ozone water (OZW). In one embodiment, the chemistry of the wet etch comprises about 0.2 3% DHF with >10 ppm OZW, preferably, the chemistry comprises about 0.5-2% DHF with >15 ppm OZW.

As discussed, there may be additional critical processes in the process flow. If necessary, an additional contamination protection layer may be formed on the wafer for the next critical process. Alternatively, a sufficient amount of contamination protection layer remains from the previous clean process to protect the wafer. After the IC is completed, the substrate is diced and the chips are packaged.

The invention has been particularly shown and described with reference to various embodiments, it will be recognized by those skilled in the art that modifications and changes may be made to the present invention without departing from the spirit and scope thereof. The scope of the invention should therefore be determined not with reference to the above description but with reference to the appended claims along with their full scope of equivalents.

1. In manufacturing of integrated circuits (ics) a method of reducing contamination comprising:
providing a substrate having top, bottom and side surfaces; and
forming a contamination protection layer on at least the bottom surface of the substrate, the contamination protection layer having a low diffusion factor which can be cleaned efficiently.

2. The method of claim 1 wherein forming the contamination layer comprises depositing the contamination protection layer on surfaces of the substrate.

3. The method of claim 2 wherein forming the contamination protection layer further comprises removing the contamination protection layer from at least a chip region on the top surface of the substrate.

4. The method of claim 1 wherein the IC comprises a memory array or memory cells.

5. The method of claim 4 wherein forming the contamination layer comprises depositing the contamination protection layer on surfaces of the substrate.

6. The method of claim 5 wherein forming the contamination protection layer further comprises removing the contamination protection layer from at least a chip region on the top surface of the substrate.

7. The method of claim 1 wherein the IC comprises a memory array of ferroelectric memory cells.

8. The method of claim 7 wherein forming the contamination layer comprises depositing the contamination protection layer on surfaces of the substrate.

9. The method of claim 8 wherein forming the contamination protection layer further comprises removing the contamination protection layer from at least a chip region on the top surface of the substrate.

10. The method of claim 1 further comprises:
subjecting the substrate to a process, wherein the process deposits harmful elements on the contamination protection layer; and
cleaning the harmful elements from the contamination layer.

11. The method of claim 10 wherein cleaning the harmful elements comprises removing at least a portion of the contamination protection layer to remove the harmful elements.

12. The method of claim 11 wherein a clean solution for cleaning the harmful elements from the contamination layer comprises 0.2-3% DHF.

13. The method of claim 11 wherein a clean solution for cleaning the harmful elements from the contamination layer comprises 0.5-2% DHF.

14. The method of claim 10 wherein the diffusion factor of the contamination protection layer is less than that of TEOS.

15. The method of claim 14 wherein the contamination protection layer comprises low k silicon nitride.

16. The method of claim 15 wherein the low k silicon nitride comprises a k less than about 7.5.

17. The method of claim 15 wherein the low k silicon nitride comprises a k less than about 7.3.

18. The method of claim 15 wherein the low k silicon nitride comprises a k from about 5-7.3.

19. The method of claim 14 wherein the contamination protection layer comprises porous silicon nitride.

20. The method of claim 19 wherein the porous silicon nitride comprises a density less than about 2.8.

21. The method of claim 20 wherein the porous silicon nitride comprises a density less than about 2.6.

22. The method of claim 10 wherein the contamination protection layer comprises an etch rate greater than about 2.5A in 1/200 diluted solution.

23. The method of claim 10 wherein the contamination protection layer comprises an etch rate greater than about 4A in 1/200 diluted solution.

24. The method of claim 10 wherein the contamination protection layer comprises an etch rate greater than about 5A in 1/200 diluted solution.
